(19) United States
(12) Patent Application Publication
(10) Pub. No.: US 2023/0275402 A1
(43) Pub. Date: Aug. 31, 2023

(54) SEMICONDUCTOR OPTICAL WAVEGUIDE INTEGRATED WITH GAIN BLOCK IN A LIGHT DETECTION AND RANGING (LIDAR) SYSTEM

(71) Applicant: LightIC Technologies HK Limited, Santa Clara, CA (US)

(72) Inventors: Jie SUN, Santa Clara, CA (US); Tianbo SUN, Santa Clara, CA (US); Xiaoning JIA, Santa Clara, CA (US)

(21) Appl. No.: 17/680,950

(22) Filed: Feb. 25, 2022

(51) Int. Cl. H01S 5/223; G01S 7/481; G02B 27/10; H01S 5/50; H01S 5/0237; H01S 5/10; H01S 5/22; H01S 5/0238

(52) U.S. Cl. CPC H01S 5/223; G01S 7/481; G02B 27/106; H01S 5/50; H01S 5/0237; H01S 5/1014; H01S 5/2214; H01S 5/0238

(57) ABSTRACT

Aspects for an on-chip or integrated Light Detection and Ranging (LiDAR) device are described herein. The aspects may include a semiconductor optical waveguide integrated in the LiDAR device. A receiving end of the semiconductor optical waveguide may receive a light beam from a light source. One or more beam splitters may be configured to split the light beam into two or more light beams. At least one semiconductor optical amplifier (SOA) may be integrated to amplify the power of the light beam or the split two or more light beams.

### INCORPORATION BY REFERENCE

All publications, patents and patent applications referred to herein are incorporated by reference in their entirety to the same extent as if each individual publication, patent or patent application was specifically and individually indicated to be incorporated by reference in its entirety.

### BACKGROUND

Unless otherwise indicated herein, the materials described in this section are not prior art to the claims in this application and are not admitted to be prior art by inclusion in this section.

LiDAR devices are now widely deployed in different scenarios including autonomous vehicles. A LiDAR device may actively estimate distances to environmental features while scanning through a scene to generate a cloud of point positions indicative of the three-dimensional shape of the environmental scene. Individual points are measured by generating a laser pulse and detecting a returning pulse reflected from a surface of an environmental object and calculating the distance to the reflective object according to the time delay between the emitted pulse and the reception of the reflected pulse, which may be commonly referred to as time of flight (TOF) method.

In many current LiDAR devices, an array of illuminators (e.g., lasers, light emitting diodes (LEDs)) may be used to obtain reflections from a wider field of view than is possible with a single illuminator. Such array of illuminators may be implemented with multiple light sources, or a single light source, coupled with beam splitters, in this scenario, the single light source needs to emit at very high power, since power of the light beams may be reduced after the splitting.

### SUMMARY

The following presents a simplified summary of one or more aspects in order to provide a basic understanding of such aspects. This summary is not an extensive overview of all contemplated aspects and is intended to neither identify key or critical elements of all aspects nor delineate the scope of any or all aspects. Its sole purpose is to present some concepts of one or more aspects in a simplified form as a prelude to the more detailed description that is presented later.

One example of the present disclosure provides an example on-chip semiconductor waveguide. The example semiconductor waveguide may include a receiving end configured to receive a light beam generated from a light source. A semiconductor optical amplifier (SOA) may be configured to receive the light beam guided from the receiving end and amplify the light beam. A beam splitter may be configured to receive the amplified light beam and split the amplified light beam into two or more beams.

Another example of the present disclosure provides another example on-chip semiconductor waveguide. The example semiconductor waveguide may include a receiving end configured to receive a light beam generated from a light source. A beam splitter may be configured to receive the light beam and split the light beam into two or more beams. Two or more SOAs may be configured to respectively receive and amplify the two or more beams.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, and in which:

FIG. 1 is a diagram illustrating a conventional semiconductor optical chip receiving a light beam from a light source;

FIG. 2 is a diagram illustrating a semiconductor optical chip including an example semiconductor waveguide in accordance with the disclosure;

FIG. 3 is a diagram illustrating a semiconductor optical chip including another example semiconductor waveguide in accordance with the disclosure;

FIG. 4 is a diagram illustrating a semiconductor optical chip including another example semiconductor waveguide in accordance with the disclosure;

FIG. 5 is a diagram illustrating a semiconductor optical chip including another example semiconductor waveguide in accordance with the disclosure;

FIG. 6 shows a perspective view of a receiving section of an example semiconductor waveguide in accordance with the disclosure;

FIG. 7 shows a perspective view of an SOA of an example semiconductor waveguide in accordance with the disclosure; and

FIG. 8 shows a perspective view of the SOA attached to the receiving section of an example semiconductor waveguide in accordance with the disclosure.

### DETAILED DESCRIPTION

Various aspects are now described with reference to the drawings. In the following description, for purpose of explanation, numerous specific details are set forth in order to provide a thorough understanding of one or more aspects. It may be evident, however, that such aspect(s) may be practiced without these specific details.

In the present disclosure, the term “comprising” and “including” as well as their derivatives mean to contain rather than limit; the term “or,” which is also inclusive, means and/or.

In this specification, the following various embodiments used to illustrate principles of the present disclosure are only for illustrative purpose, and thus should not be understood as limiting the scope of the present disclosure by any means. The following description taken in conjunction with the accompanying drawings is to facilitate a thorough understanding of the illustrative embodiments of the present disclosure defined by the claims and its equivalent. There are specific details in the following description to facilitate understanding. However, these details are only for illustrative purpose. Therefore, persons skilled in the art should understand that various alternation and modification may be made to the embodiments illustrated in this description without going beyond the scope and spirit of the present disclosure. In addition, for clear and concise purpose, some known functionality and structure are not described. Besides, identical reference numbers refer to identical function and operation throughout the accompanying drawings.

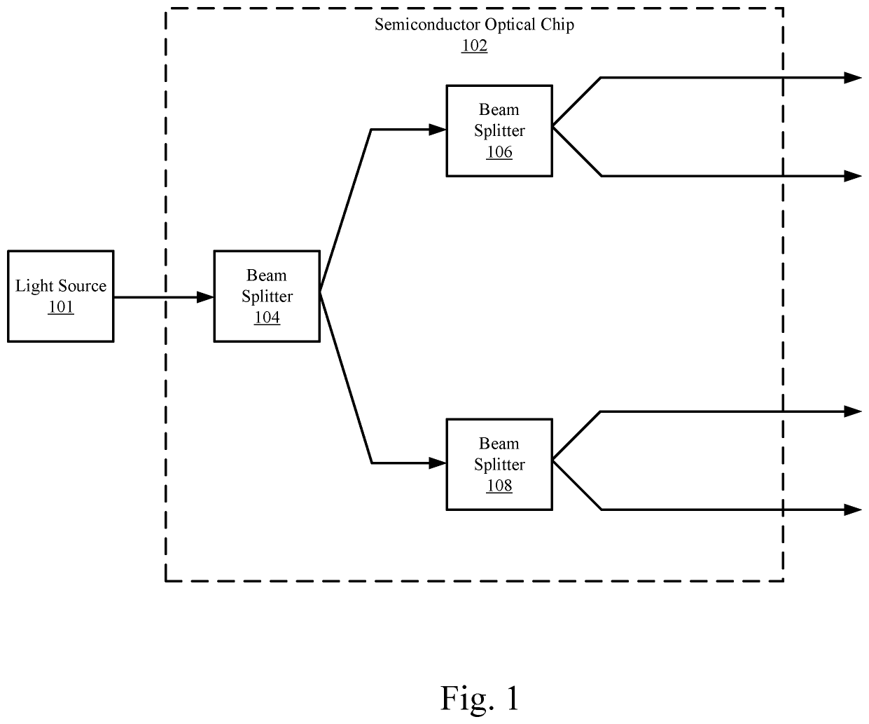

FIG. 1 is a diagram illustrating a conventional semiconductor optical chip receiving a light beam from a light source, and distribute the light into one or more channels.

As depicted, a conventional semiconductor optical chip, e.g., a semiconductor optical chip 102, may be integrated in a LiDAR system. The semiconductor optical chip 102 may include a semiconductor waveguide configured to receive a light beam from a light source 101, e.g., a laser generator. The light beam may be directed to a beam splitter 104 and split into two or more light beams by the beam splitter 104. Each of the two or more light beams may be further directed to other beam splitters such as beam splitters 106 and 108. The beam splitters 106 and 106 may further split the two or more light beams into four or more light beams. As previously stated, the respective powers of the four or more light beams may be substantially lower than the light beam initially generated by the light source 101.

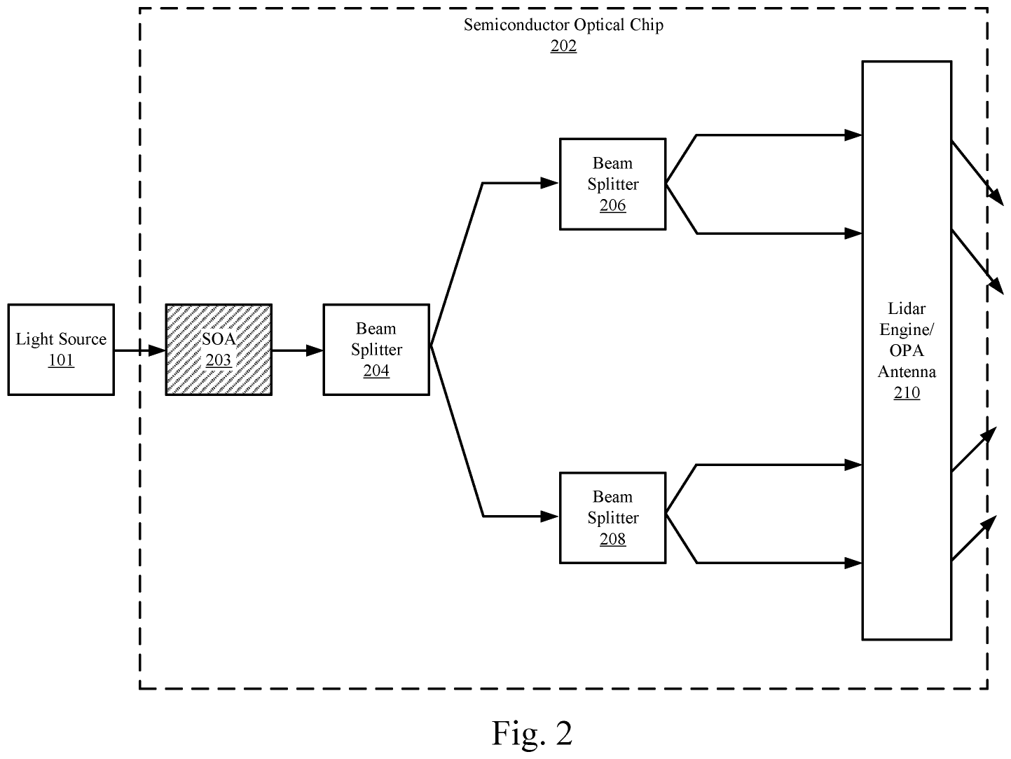

FIG. 2 is a diagram illustrating a semiconductor optical chip including an example semiconductor waveguide in accordance with the disclosure.

To overcome the deficiency of the conventional structure as described above, one or more semiconductor optical amplifier (SOA) may be included in the semiconductor optical chip to increase the powers of the split light beams. For example, an SOA 203 may be included in the semiconductor waveguide of a semiconductor optical chip 202. The SOA 203 may receive the light beam initially generated by the light source 101 and may be configured to amplify the power of the light beam. The amplified light beam may then be directed to a beam splitter 204 and, subsequently, beam splitters 206 and 208. Although not shown in FIG. 2, multiple SOAs can be implemented in the semiconductor optical chip 202, for example, between the beam splitter 204 and the beam splitter 206. The split light beams from the beam splitters 206 and 208 may be further directed to a Frequency-Modulated Continuous Wave (FMCW) LiDAR engine or an antenna of an optical phased array (OPA) 210 on the semiconductor optical chip. The FMCW LiDAR engine or the antenna of the OPA 210, as a part of a LiDAR system, may further direct the light beams to one or more intended directions to detect surrounding objects.

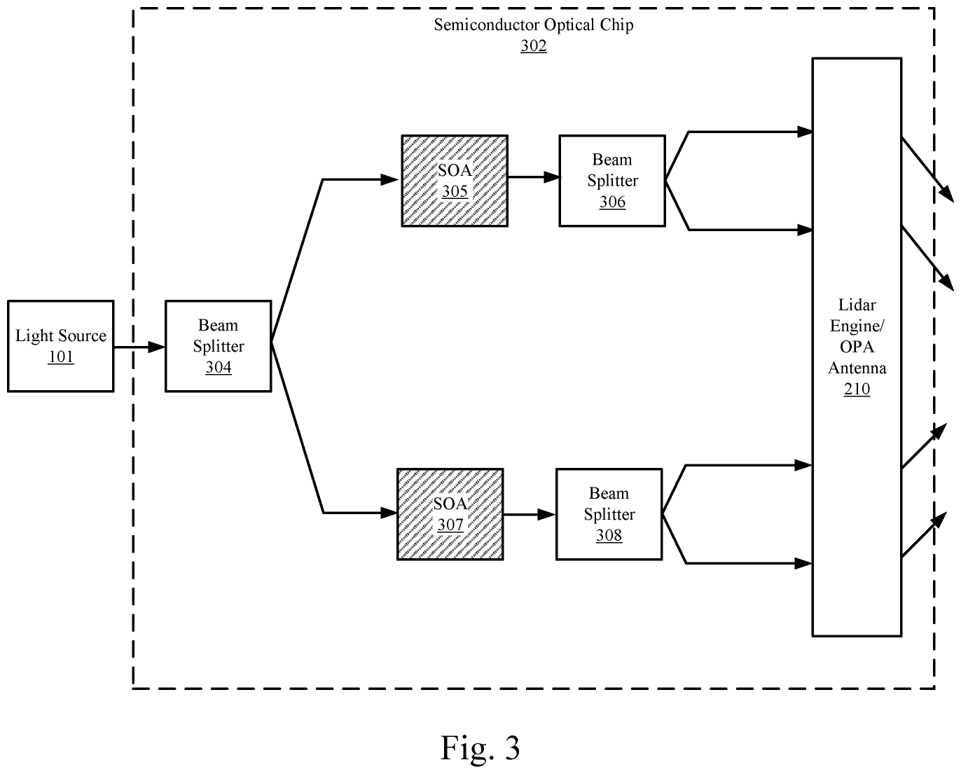

FIG. 3 is a diagram illustrating a semiconductor optical chip including another example semiconductor waveguide in accordance with the disclosure. The example semiconductor waveguide may include a beam splitter 304 receiving the light beam directed from the light source 101. The beam splitter 304 may be configured to split the light beam into two or more light beams. Respectively, two or more SOAs may be integrated in the semiconductor waveguide to receive and amplify the two or more light beams. The amplified two or more light beams may be directed to beam splitters 306 and 308 and further split into four or more light beams by the beam splitters 306 and 308. Similarly, the four or more light beams from the beam splitters may be further amplified by additional SOAs or may be directed to next functional block on the same chip or another chip. One example of the functional block is FMCW LiDAR engine described in U.S. patent application Ser. No. 16/907,837.

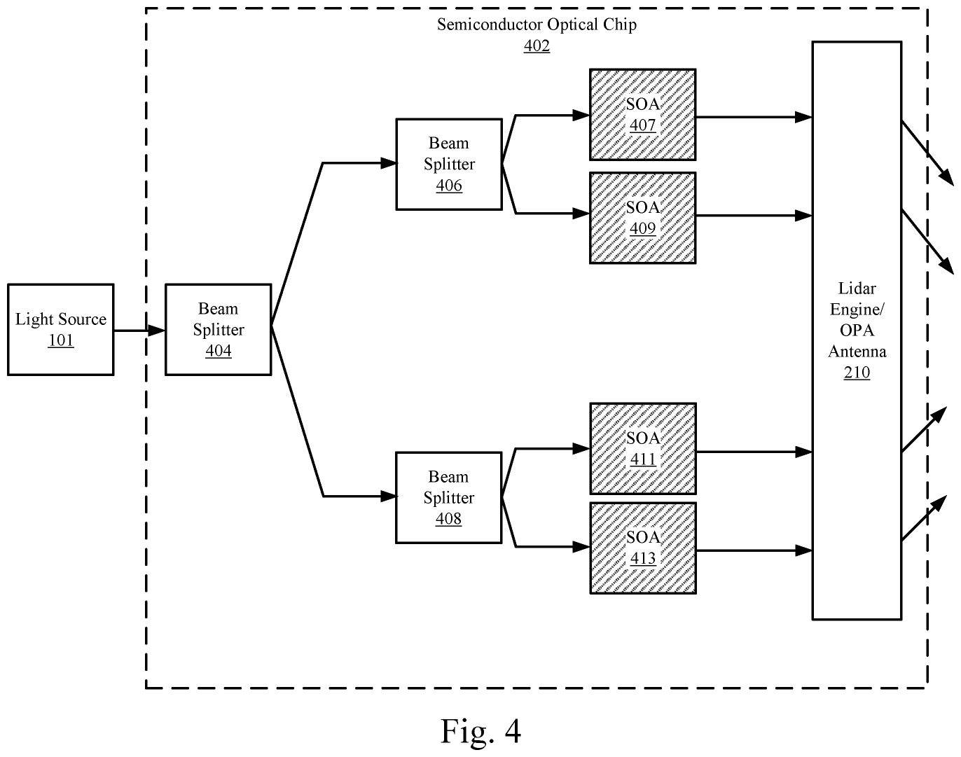

FIG. 4 is a diagram illustrating a semiconductor optical chip including another example semiconductor waveguide in accordance with the disclosure. The example semiconductor waveguide, as depicted, may include a beam splitter 404 configured to receive the light beam and split the light beam into two or more light beams. The two or more light beams may be further directed to and split by beam splitters 406 and 408 into four or more light beams. Multiple SOAs 407, 409, 411, and 413 may be integrated in the semiconductor waveguide and amplify the four or more light beams. Similarly, the four or more light beams from the beam splitters may be further amplified by additional SOAs or may be directed to next functional block on the same chip or another chip. One example of the functional block is FMCW LiDAR engine described in U.S. patent application Ser. No. 16/907,837.

Note that one or more additional SOAs may be integrated to receive and amplify the light beam from the light source 101 or the light beams from the beam splitter 404.

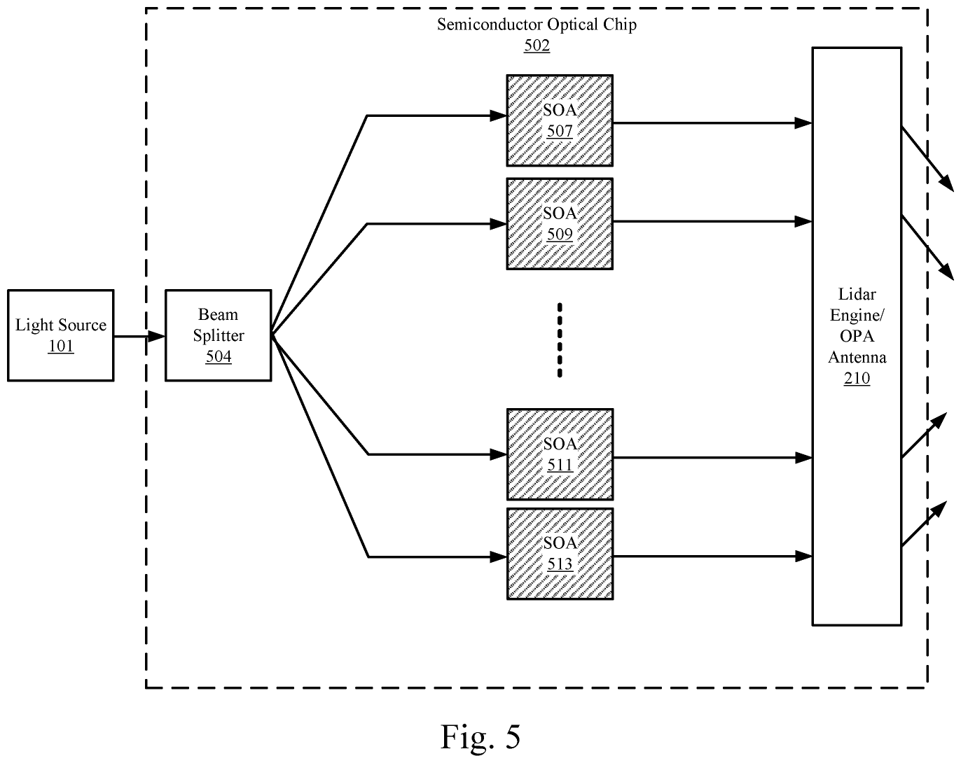

FIG. 5 is a diagram illustrating a semiconductor optical chip including another example semiconductor waveguide in accordance with the disclosure. The example semiconductor waveguide, as depicted, may include a beam splitter 504 configured to split the light beam from the light source 101 into more than two light beams, e.g., four light beams as illustrated. The light beams may be directed respectively to SOAs 507, 509, 511, and 513. The SOAs 507, 509, 511, and 513 may be configured to amplify the light beams. The amplified light beams may be directed to next functional block on the same chip or another chip. One example of the functional block is FMCW LiDAR engine described in U.S. patent application Ser. No. 16/907,837.

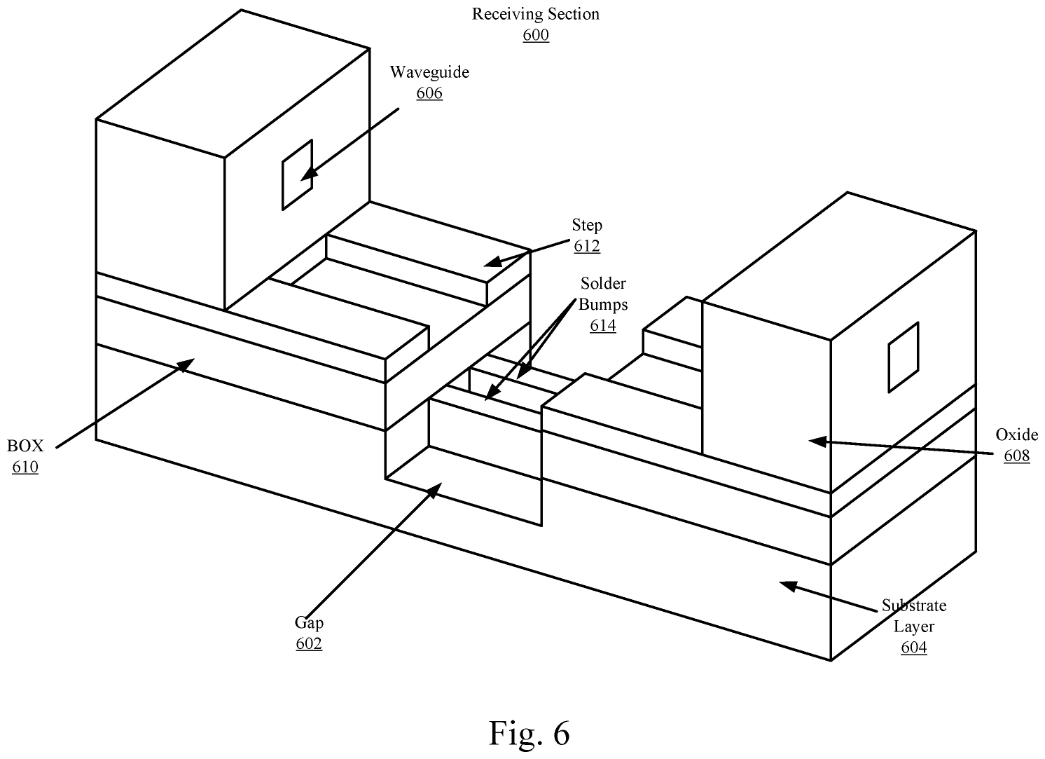

FIG. 6 shows a perspective view of an example receiving section of an example semiconductor waveguide in accordance with the disclosure.

As depicted, the example receiving section 600 may be formed on a substrate layer 604. The substrate layer 604 may be made of silicon. A buried oxide layer (e.g., BOX 610) may be further deposited on the substrate layer 604. A gap 602 may be formed on the BOX 610 and the substrate layer 604 by an etching process. Two solder bumps 614 may be bonded to at the gap 602 for receiving electrodes. One more step, e.g., step 612, may be deposited on top of the BOX 610. The step 612 may be elongated extending at a direction. An oxide layer, e.g., oxide 608, may be deposited on the layer of the step 612. A waveguide 606 may be formed inside the oxide 608 extending at the same direction as the step 612.

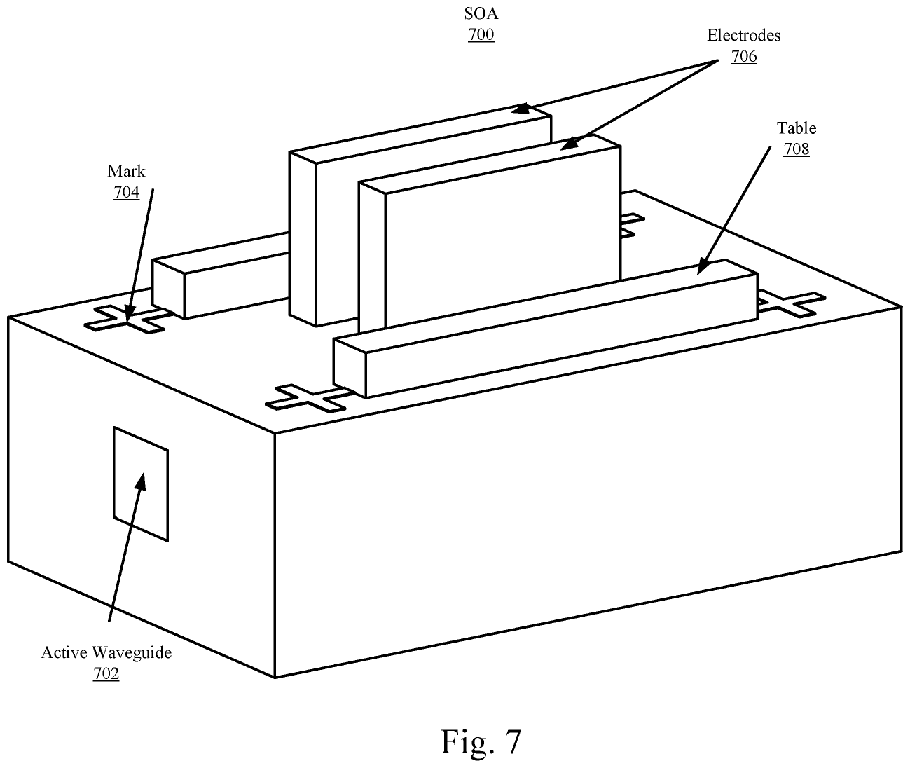

FIG. 7 shows a perspective view of an example SOA of an example semiconductor waveguide in accordance with the disclosure. The example SOA 700, as depicted, may include an active waveguide 702 buried inside. The example SOA 700 may be made of III-V compound semiconductor materials such as GaSb, GaAS, InP, ZnS, etc. One or more marks, e.g., mark 704, may be imprinted on a first surface of the SOA 700 for alignment. One or more tables, e.g., table 708, may be formed on the first surface of the SOA 700. The table 708 may also be formed via an etching process. Further, a positive electrode and a negative electrode, e.g., electrodes 706, may be fabricated between the tables.

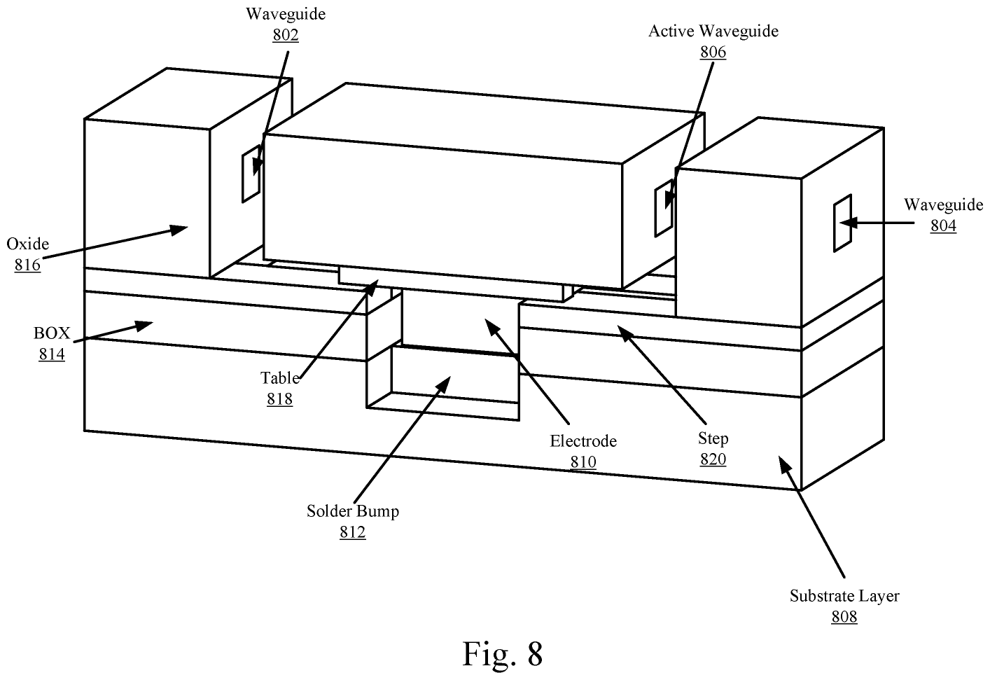

FIG. 8 shows a perspective view of the SOA integrated to the receiving section of an example semiconductor waveguide in accordance with the disclosure.

In some examples, the SOA 700 may be integrated to the receiving section 600 of the semiconductor waveguide as depicted via different processes. For instance, the SOA 700 may be integrated to the semiconductor optical chip via wafer bonding, die bonding, or Micro-Transfer-Printing. Alternatively, III-V semiconductor materials may be directly grown on the semiconductor optical chip and fabricated into an SOA via etching. Further, a trench, e.g., gap 602, may be formed on the semiconductor optical chip and the SOA 700 may be welded to the semiconductor optical chip, e.g., semiconductor optical chip 202, 302, 402, or 502.

As depicted, the positive electrode and the negative electrode, e.g., electrode 810, may be welded to the solder bumps, e.g., solder bump 812, of the semiconductor optical chip. When powered through the positive electrode and the negative electrode via the solder bumps 812, the SOA may then amplify the power of the light beam transmitted from waveguide 802.

A table 818 of the SOA may be in contact with a step 820 of the receiving section. The thickness of the table 818 may be accurately controlled such that the active waveguide 806 inside the SOA may be aligned with the waveguides 802 and 804. The thickness of the electrodes, e.g., the electrode 810, may also be accurately controlled to align the active waveguide 806 with the waveguide 802 and 804.

In some examples, a spot size converter may be inserted between the waveguide 802 and the active waveguide 806 and/or between the active waveguide 806 and the waveguide 804 such that the size of the light beam travelling from the waveguide 802 may be adjusted to fit the active waveguide 806; similarly, the size of the light beam travelling from the active waveguide 806 may be adjusted to fit the waveguide 804. The matching between the two spots will increase the coupling efficiency.

In the above description, each embodiment of the present disclosure is illustrated with reference to certain illustrative embodiments. Apparently, various modifications may be made to each embodiment without going beyond the wider spirit and scope of the present disclosure presented by the affiliated claims. Correspondingly, the description and accompanying figures should be understood as illustration only rather than limitation. It is understood that the specific order or hierarchy of steps in the processes disclosed is an illustration of exemplary approaches. Based upon design preferences, it is understood that the specific order or hierarchy of steps in the processes may be rearranged. Further, some steps may be combined or omitted. The accompanying method claims present elements of the various steps in a sample order and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described herein that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

Moreover, the term “or” is intended to mean an inclusive “or” rather than an exclusive “or.” That is, unless specified otherwise, or clear from the context, the phrase “X employs A or B” is intended to mean any of the natural inclusive permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

We claim:

1. A Light Detection and Ranging (LiDAR) chip, comprising:
a semiconductor waveguide that includes a receiving end configured to receive a light beam;
a semiconductor optical amplifier (SOA) configured to receive the light beam guided from the receiving end and amplify the light beam; and
a beam splitter configured to receive the amplified light beam and split the amplified light beam into two or more beams.

2. The LiDAR chip of claim 1, further comprising two or more secondary SOAs configured to respectively amplify the two or more beams.

3. The LiDAR chip of claim 1, further comprising a Frequency-Modulated Continuous Wave (FMCW) LiDAR engine or an antenna of an optical phased array (OPA) configured to receive the two or more beams and direct the two or more beams to at least one intended direction.

4. The LiDAR chip of claim 2, further comprising two or more secondary beam splitters configured to respectively split each of the amplified two or more beams.

5. The LiDAR chip of claim 1, further comprising:
a gap formed at a substrate layer;
a buried oxide (BOX) layer on the substrate layer on two sides of the gap;
a step formed on the BOX layer and elongated at a direction; and
an oxide layer formed on the BOX layer on the two sides of the gap, wherein two waveguides are buried inside the oxide layer and extended at the direction.

6. The LiDAR chip of claim 5, further comprising two solder bumps fixed at the gap formed at the substrate layer.

7. The LiDAR chip of claim 6, wherein the SOA includes:
a table formed on a first surface, wherein the table is in contact with the step; and
a positive electrode and a negative electrode deposited on the first surface, wherein the positive electrode and the negative electrode are in contact with the solder bumps respectively.

8. The LiDAR chip of claim 7, wherein the SOA further includes an active optical waveguide buried inside and extended at the direction of the step to connect the two waveguides in the oxide layer.

9. The LiDAR chip of claim 7, wherein the SOA includes one or more marks for aligning the SOA with a receiving section formed by the gap.

10. The LiDAR chip of claim 8, wherein a depth of the gap equals a summation of:
a distance between a surface of the step and a center of one of the two waveguides in the oxide layer, and
a distance between the first surface and a center of the active optical waveguide.

11. The LiDAR chip of claim 8, wherein a spot size converter is inserted between the waveguide and the active optical waveguide.

12. A LiDAR chip, comprising
a semiconductor waveguide that includes a receiving end configured to receive a light beam;
a beam splitter configured to receive the light beam and split the light beam into two or more beams; and
two or more semiconductor optical amplifiers (SOAs) configured to respectively receive and amplify the two or more beams.

13. The LiDAR chip of claim 12, further comprising two or more secondary beam splitters configured to respectively split the amplified two or more beams.

14. The LiDAR chip of claim 12, further comprising a Frequency-Modulated Continuous Wave (FMCW) LiDAR engine or an antenna of an optical phased array (OPA) configured to receive the amplified two or more beams and direct the amplified two or more beams to at least one intended direction.

15. The LiDAR chip of claim 12, further comprising:
a gap formed at a substrate layer;
a buried oxide (BOX) layer on the substrate layer on two sides of the gap;
a step formed on the BOX layer and elongated at a direction; and
an oxide layer formed on the BOX layer on the two sides of the gap, wherein two waveguides are buried inside the oxide layer and extended at the direction.

16. The LiDAR chip of claim 15, further comprising two solder bumps fixed at the gap formed at the substrate layer.

17. The LiDAR chip of claim 16, wherein each of the two or more SOAs includes:
a table formed on a first surface, wherein the table is in contact with the step; and
a positive electrode and a negative electrode deposited on the first surface, wherein the positive electrode and the negative electrode are in contact with the solder bumps respectively.

18. The LiDAR chip of claim 17, wherein each of the two or more SOAs further includes an active optical waveguide buried inside and extended at the direction of the step to connect the two waveguides in the oxide layer.

19. The LiDAR chip of claim 17, wherein the SOA includes one or more marks for aligning the SOA with a receiving section formed by the gap.

20. The LiDAR chip of claim 18, wherein a depth of the gap equals a summation of:
a distance between a surface of the step and a center of one of the two waveguides in the oxide layer, and
a distance between the first surface and a center of the active optical waveguide.

21. The LiDAR chip of claim 18, wherein a spot size converter is inserted between the waveguide and the active optical waveguide.
